(19) United States
(12) Patent Application Publication
(10) Pub. No.: US 2015/0136024 A1
(43) Pub. Date: May 21, 2015

(54) LIQUID DISCHARGE HEAD

(71) Applicant: CANON KABUSHIKI KAISHA, Tokyo (JP)

(72) Inventors: Souta Takeuchi, Fujisawa-shi (JP); Hirokazu Komuro, Yokohama-shi (JP); Takuya Hatsui, Tokyo (JP); Makoto Sakurai, Kawasaki-shi (JP); Takeru Yasuda, Kawasaki-shi (JP); Soichiro Nagamochi, Kawasaki-shi (JP); Masaya Uyama, Kawasaki-shi (JP); Seiko Minami, Warabi-shi (JP); Hiroshi Higuchi, Atsugi-shi (JP)

(21) Appl. No.: 14/400,523

(22) PCT Filed: Apr. 22, 2013
(86) PCT No.: PCT/JP2013/002704

§ 371 Date: Nov. 11, 2014

(30) Foreign Application Priority Data
May 16, 2012 (JP) 2012-112718

(51) Int. Cl. C23C 16/50; C23C 16/458

(52) U.S. Cl. CPC C23C 16/50; C23C 16/4583
USPC 118/723 R; 427/248.1; 264/219

(57) ABSTRACT

A liquid discharge head has a substrate, an energy generating element which generates energy for discharging liquid, and an orifice plate in which a discharge orifice which discharges liquid is formed, in which the orifice plate contains silicon and carbon and when the content ratio of the silicon is defined as X (atom %) and the content ratio of the carbon is defined as Y (atom %), Y/X is 0.001 or more.

### TECHNICAL FIELD

The present invention relates to a liquid discharge head.

### BACKGROUND ART

An ink jet recording apparatus has a liquid discharge head which discharges liquid. The liquid discharge head generally has a substrate, an energy generating element which generates energy for discharging liquid, and an orifice plate, in which the orifice plate has a discharge orifice which discharges liquid.

As the orifice plate, there are those formed with organic materials containing resin and the like. On the other hand, there are orifice plates formed with inorganic materials, such as silicon oxide and silicon nitride (PTL 1 and PTL 2). The liquid discharge head having such an orifice plate is generally known as a liquid discharge head provided with an inorganic nozzle.

In recent years, ink which has been improved in various ways as liquid to be discharged has been proposed. The improvement of ink has been performed by various techniques. There are various ink types in which color materials are different, such as dyes and pigments, a solvent is also improved in order to stably dissolve color materials, and the pH varies from acidic to alkaline.

The liquid discharge head has been required to favorably discharge such various types of ink To that end, the orifice plate has been required to be hard to undergo dissolution or deformation and to stably maintain the shape in the case of various types of ink

### CITATION LIST

### Patent Literature

PTL 1: U.S. Pat. No. 6,482,574

PTL 2: U.S. Pat. No. 7,600,856

### SUMMARY OF INVENTION

The present invention provides a liquid discharge head having a substrate, an energy generating element which generates energy for discharging liquid, and an orifice plate in which a discharge orifice which discharges liquid is formed, in which the orifice plate contains silicon and carbon and when the content ratio of the silicon is defined as X (atom %) and the content ratio of the carbon is defined as Y (atom %), Y/X is 0.001 or more.

The invention can provide a liquid discharge head having an orifice plate which is hard to dissolve in liquid to be discharged and whose shape is stable.

### BRIEF DESCRIPTION OF DRAWINGS

FIG. 1 illustrates one example of a perspective view of a liquid discharge head of the invention.

FIG. 2 illustrates one example of a cross sectional view of the liquid discharge head of the invention.

FIG. 3A illustrates one example of a cross sectional view illustrating a method for manufacturing the liquid discharge head of the invention.

FIG. 3B illustrates one example of a cross sectional view illustrating a method for manufacturing the liquid discharge head of the invention.

FIG. 3C illustrates one example of a cross sectional view illustrating a method for manufacturing the liquid discharge head of the invention.

FIG. 3D illustrates one example of a cross sectional view illustrating a method for manufacturing the liquid discharge head of the invention.

FIG. 3E illustrates one example of a cross sectional view illustrating a method for manufacturing the liquid discharge head of the invention.

FIG. 3F illustrates one example of a cross sectional view illustrating a method for manufacturing the liquid discharge head of the invention.

### DESCRIPTION OF EMBODIMENT

According to the examination of the present inventors, when a liquid discharge head having an orifice plate described in PTL 1 and PTL 2 has been used, the orifice plate has dissolved and deformed in some cases. It has found that particularly when an alkaline ink having a pH of about 8 to 9 or an ink containing a pigment as a color material and the orifice plate contact over a long period of time, the dissolution and the deformation of the orifice plate are likely to occur.

The invention solves the above-described problems and provides a liquid discharge head having an orifice plate which is hard to dissolve in liquid to be discharged and whose shape is stable.

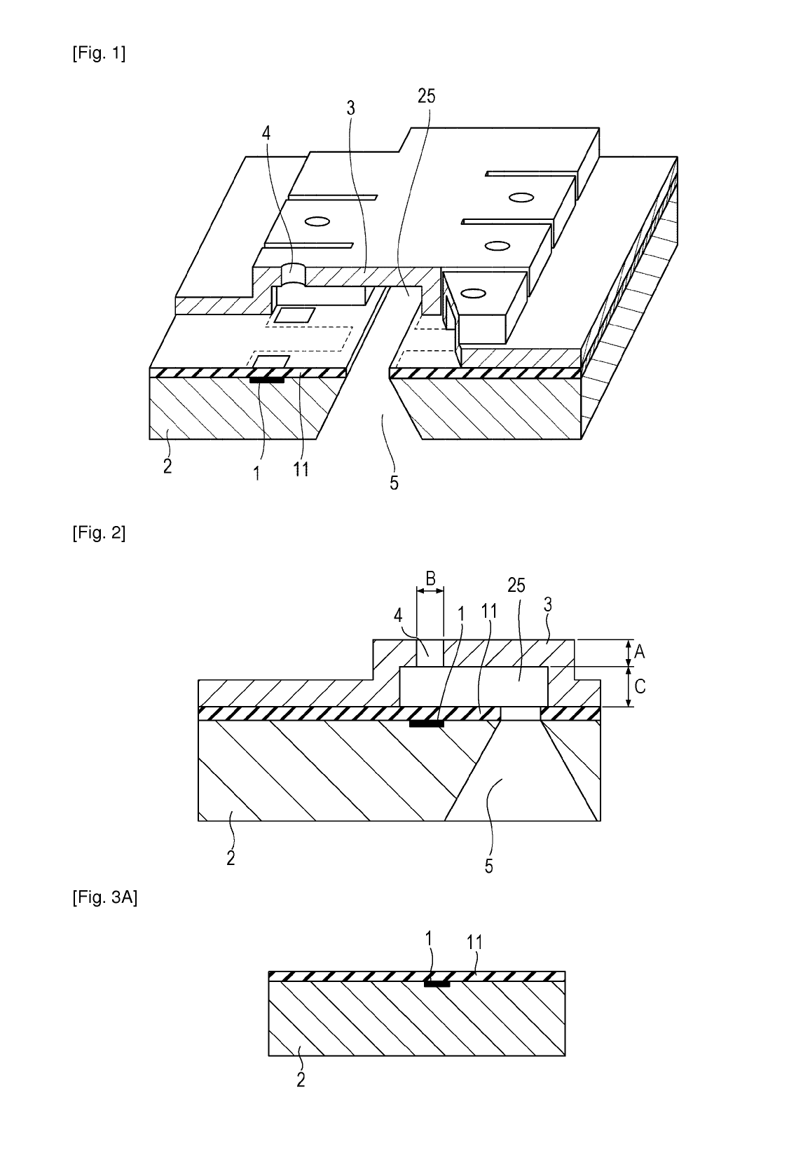

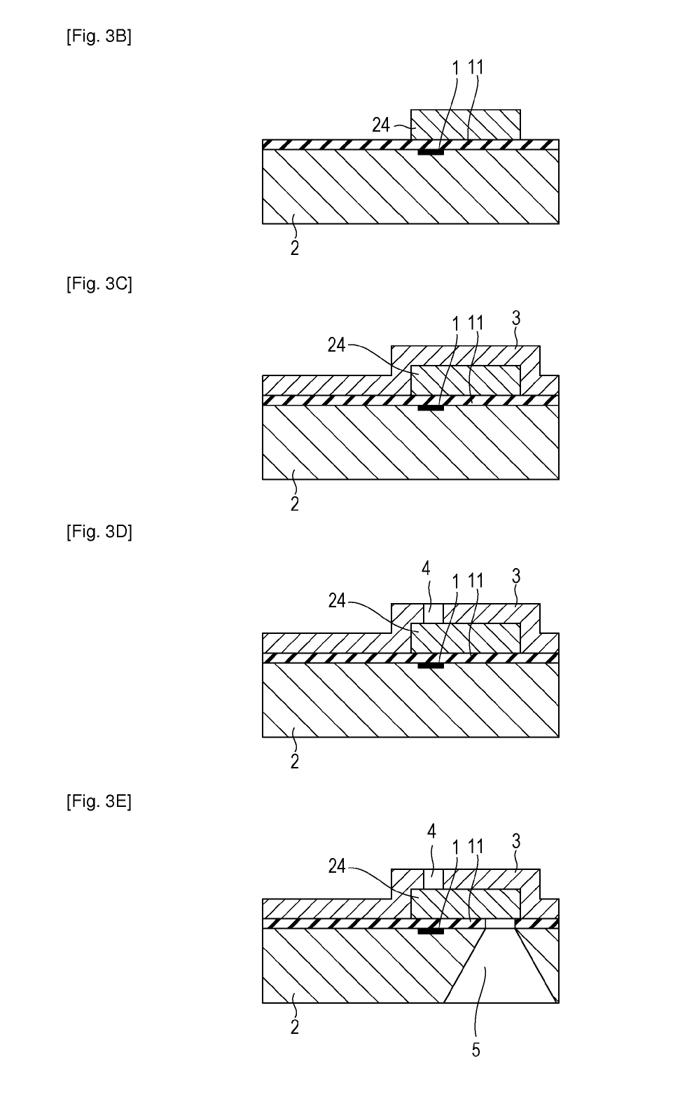

The liquid discharge head of the invention is described with reference to FIGS. 1 and 2. FIG. 1 is a perspective view of the liquid discharge head. FIG. 2 is a cross sectional view of the liquid discharge head of FIG. 1.

As illustrated in FIGS. 1 and 2, the liquid discharge head has an orifice plate 3 in which a discharge orifice 4 which discharges liquid is formed on a substrate 2. The substrate 2 is formed with silicon or the like. An energy generating element 1 is formed at the side where the orifice plate 3 is provided of the substrate 2. The energy generating element 1 in FIGS. 1 and 2 is a thermoelectric conversion element (heater). As the energy generating element, a piezoelectric element and the like may be used. The energy generating element 1 may not contact the substrate 2 and may float in the air relative to the substrate 2. In FIGS. 1 and 2, the energy generating element 1 is covered with an insulating protective film 11.

The substrate 2 has a liquid supply orifice 5. Liquid is supplied from the liquid supply orifice 5, passes through a flow path 25, and is discharged from the discharge orifice 4 while energy being given from the energy generating element 1.

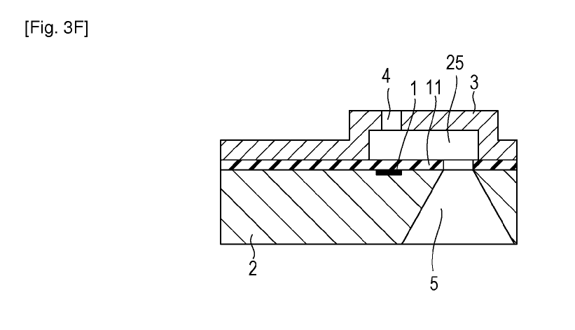

Next, a method for manufacturing the liquid discharge head of the invention is described with reference to FIG. 3.

First, as illustrated in FIG. 3A, the substrate 2 having the energy generating element 1 is prepared. The energy generating element is formed with TaSiN or the like and is covered with the protective film 11.

Next, as illustrated in FIG. 3B, a molding member 24 serving as the mold of the flow path is provided on the substrate 2. The molding member 24 is formed with resin, for example. When the resin is a photosensitive resin, a method is mentioned which includes applying the photosensitive resin onto the substrate, exposing and developing the photosensitive resin, and then patterning, thereby forming a molding member serving as the mold of the flow path. When the resin is not a photosensitive resin, a method is mentioned which includes providing a photosensitive resin on resin serving as a molding member, patterning the photosensitive resin to form a resist, and then etching the resin using the resist by RIE or the like. The molding member 24 is not limited to resin and may be formed with metal, such as aluminum. When using aluminum, a method is mentioned which includes forming aluminum into a film by sputtering on the substrate 2, forming a resist with a photosensitive resin or the like on the aluminum, and then etching the aluminum using the resist by RIE or the like.

Next, as illustrated in FIG. 3C, a layer serving as the orifice plate 3 is formed on the upper surface of the molding member 24. The layer serving as the orifice plate 3 is formed in such a manner as to cover the molding member 24 from the upper surface of the molding member 24. Although the orifice plate 3 may be formed by any method, the orifice plate 3 is suitably formed by a plasma CVD method. The layer serving as the orifice plate 3 is suitably extended from the molding member 24 and formed onto the substrate 2 and, when the protective film 11 is provided, also onto the protective film. The orifice plate is a plate in which a discharge orifice is formed. The thickness of the orifice plate is suitably 1 micrometer or more and 30 micrometer or lower. The thickness is more suitably 2 micrometer or more and suitably exceeds 5 micrometer.

Next, as illustrated in FIG. 3D, the discharge orifice 4 which discharges liquid is formed in the orifice plate 3. The discharge orifice 4 is formed by, for example, etching the orifice plate 3 by RIE or irradiating the same with laser. The discharge orifice 4 is formed in such a manner as to penetrate the orifice plate 3.

Next, as illustrated in FIG. 3E, a liquid supply orifice 5 is formed in the substrate 2. The liquid supply orifice 5 is formed by, for example, irradiating the substrate 2 with laser or anisotropically etching the same. When the protective film 11 is formed on the substrate 2, the protective film 11 present on an opening portion of the liquid supply orifice is removed by RIE or the like, so that the liquid supply orifice 5 penetrates the substrate 2. The liquid supply orifice 5 may not be formed in this stage. For example, the liquid supply orifice 5 may be formed in the substrate beforehand in the stage of FIG. 3A. When considering the film formability of the molding member 24 and the like, it is suitable to form the liquid supply orifice 5 after forming the molding member 24 and the orifice plate 3.

Finally, as illustrated in FIG. 3F, the molding member 24 is removed by isotropically dry etching, a suitable solvent, or the like, thereby forming the flow path 25 for liquid. The flow path 25 also serves as a liquid chamber.

Through the processes described above, the liquid discharge head of the invention is manufactured.

With respect to the above-described orifice plate 3, the present inventors have found that, by increasing the content ratio of carbon to silicon in the orifice plate, the orifice plate becomes hard to dissolve in liquid to be discharged and stably maintains the shape. More specifically, the orifice plate 3 contains silicon and carbon and when the content ratio of the silicon is defined as X (atom %) and the content ratio of the carbon is defined as Y (atom %), Y/X is 0.001 or more. The liquid discharge head of the invention is a liquid discharge head provided with a so-called inorganic nozzle. Y/X is more suitably 0.001 or more and still more suitably 0.05 or more and 0.1 or more. From the viewpoint of the film formability, Y/X is suitably 10 or lower. The silicon and the carbon in the orifice plate are suitably present as silicon carbide.

The total amount of the silicon and the carbon, i.e., X+Y, is suitably 50 or more. The orifice plate may contain only silicon and carbon. In such a case, X+Y=100 is given.

The orifice plate 3 suitably contains nitrogen in many cases and suitably contains nitrogen with silicon and carbon as silicon carbonitride. By compounding nitrogen, the insulation properties of the orifice plate can be improved. When the content ratio of the nitrogen in the orifice plate is defined as Z (atom %), X+Y+Z suitably exceeds 50. The orifice plate may contain only silicon, carbon, and nitrogen. In such a case, X+Y+Z=100 is given.

The energy generating element is suitably covered with the protective film. In this case, the protective film covering the energy generating element suitably contains silicon carbonitride and is more suitably formed with only by silicon carbonitride. By forming the protective film containing silicon carbonitride, the insulation properties can be improved and the resistance to ink and the like can be improved.

When the orifice plate contains silicon carbonitride, it is suitable that the silicon carbonitride contained in the orifice plate and the silicon carbonitride contained in the protective film have the same composition. By using the same composition, a liquid discharge head can be manufactured using a single film forming apparatus.

### EXAMPLES

### Examples 1 to 8

A method for manufacturing liquid discharge heads of Examples 1 to 8 is described with reference to FIG. 3.

First, as illustrated in FIG. 3A, the substrate 2 having the energy generating element 1 formed with TaSiN was prepared. The energy generating element 1 is covered with the protective film 11 with a thickness of 0.5 micrometer containing silicon nitride given by a plasma CVD method. The substrate 2 is formed with silicon and has a thickness of 625 micrometer.

Next, polyimide (manufactured by HD Microsystems) was spin coated onto the substrate 2 at with a thickness of 2 micrometer to 23 micrometer. A resist containing a photosensitive resin was applied onto the polyimide formed into a film, the resist was exposed and developed to be used as a mask. The polyimide was etched using the resist serving as the mask by RIE, thereby forming the molding member 24 serving as the mold of the flow path (FIG. 3B).

Next, as illustrated in FIG. 3C, a layer serving as the orifice plate 3 was formed on the upper surface of the molding member 24. The layer serving as the orifice plate 3 was formed in such a manner as to cover the molding member 24 from the upper surface of the molding member 24. The layer serving as the orifice plate 3 was formed by forming silicon carbide (SiC) or silicon carbonitride (SiCN) into a film by a plasma CVD method.

The silicon carbide was prepared as appropriate according to the thickness and the content ratio of silicon and carbon of the layer serving as the orifice plate 3 under the film formation conditions of a SiH₄ gas flow rate of 80 sccm to 1 slm, a CH₄ gas flow rate of 10 sccm to 5 slm, an HRF electric power of 250 W to 900 W, an LRF electric power of 8 W to 500 W, a pressure of 310 Pa to 700 Pa, and a temperature of 300 degree celsius to 450 degree celsius.

The silicon carbonitride was prepared as appropriate according to the thickness and the content ratio of silicon, carbon, and nitrogen of the layer serving as the orifice plate 3 under the film formation conditions of a SiH₄ gas flow rate of 80 sccm to 1 slm, an NH₃ gas flow rate of 14 sccm to 400 sccm, an N₂ gas flow rate of 0 slm to 10 slm, a CH₄ gas flow rate of 10 sccm to 5 slm, an HRF electric power of 250 W to 900 W, an LRF electric power of 8 W to 500 W, a pressure of 310 Pa to 700 Pa, and a temperature of 300 degree celsius to 450 degree celsius.

Next, as illustrated in FIG. 3D, the discharge orifice 4 which discharges liquid is formed in the layer serving as the orifice plate 3, and thus the orifice plate was formed. The discharge orifice 4 was formed by applying a resist containing a photosensitive resin onto the layer serving as the orifice plate 3, and exposing and developing the resist, and then etching using the resist by RIE. The diameter of the discharge orifice 4 was 1 micrometer to 15 micrometer by adjusting the shape of the resist.

Next, as illustrated in FIG. 3E, the liquid supply orifice 5 was formed in the substrate 2. The liquid supply orifice 5 was formed by anisotropically etching the substrate 2 containing silicon using a TMAH (tetramethyl ammonium hydroxide) solution. By setting the crystal orientation of the plane where the etching of the substrate 2 is started to <100>, the liquid supply orifice 5 having the shape as illustrated in FIG. 3E was obtained. The protective film 11 on the liquid supply orifice 5 was removed by RIE, so that the liquid supply orifice 5 penetrated the substrate.

Finally, as illustrated in FIG. 3F, the molding member 24 was removed by isotropically dry etching including introducing oxygen gas, and then exciting plasma by microwaves, thereby forming the flow path 25.

The liquid discharge heads of Example 1-1 to Example 8-6 shown in Table 1 were manufactured as described above. Y/X shown in Table 1 is a value when the content ratio of the silicon of the orifice plate is defined as X (atom %) and the content ratio of the carbon of the orifice plate is defined as Y (atom %). For the orifice plate containing silicon carbonitride (SiCN), the content ratio of the nitrogen is shown together. The orifice plates of Example 1-1 to Example 4-6 have a composition of containing only silicon carbide and the orifice plates of Example 5-1 to Example 8-6 have a composition of containing only silicon carbonitride.

The cross sectional view of the manufactured liquid discharge heads is as illustrated in FIG. 2. In Table 1, the thickness of the orifice plate refers to a length of a portion of A illustrated in FIG. 2. The diameter of the discharge orifice is a length of a portion of B illustrated in FIG. 2. The height of the liquid chamber is a length of a portion of C illustrated in FIG. 2.

### Comparative Examples 1 to 2

A layer serving as the orifice plate 3 was formed by forming silicon oxide (SiO) and silicon nitride (SiN) into a film by a plasma CVD method. The thickness of the silicon oxide and the silicon nitride formed into a film, i.e., the thickness of the orifice plate, was set in the range of 1 micrometer to 15 micrometer. The liquid discharge heads of Comparative Example 1-1 to Comparative Example 1-6 and Comparative Example 2-1 to Comparative Example 2-6 shown in Table 2 were manufactured in the same manner as in Examples except the conditions above.

Evaluation

The manufactured liquid discharge heads were immersed in a pigment ink having a pH of 8.5 (70 degree celsius) for one month. Then, the shapes of the orifice plate and the discharge orifice were observed under a microscope, and then evaluated according to the following criteria.

Shape of Orifice Plate

1 Deformation of the orifice plate is hardly observed.

2 Deformation of the orifice plate is observed.

3 The orifice plate is entirely or mostly destroyed.

Shape of Discharge Orifice

1 Deformation of the discharge orifice is hardly observed.

2 Deformation of the discharge orifice is slightly observed.

3 The shape of the discharge orifice is deformed to be lost.

The evaluation results above are shown in Tables 1 and 2.

TABLE 1

| | Orifice Plate | OP | | Discharge Orifice | | Liquid Chamber | | OP | Discharge |
|---|---|---|---|---|---|---|---|---|---|
| Examples | (OP) material | Thickness: A | | Diameter: B | | Height: C | | Shape | Orifice Shape |
| 1-1 | SiC | 1 | μm | φ1 | μm | 2 | μm | 2 | 2 |
| 1-2 | (Y/X = 0.001) | 2 | μm | φ2 | μm | 3 | μm | 2 | 2 |
| 1-3 | | 3 | μm | φ3 | μm | 5 | μm | 2 | 2 |
| 1-4 | | 5 | μm | φ5 | μm | 8 | μm | 1 | 1 |
| 1-5 | | 10 | μm | φ10 | μm | 15 | μm | 1 | 1 |
| 1-6 | | 15 | μm | φ15 | μm | 23 | μm | 1 | 1 |
| 2-1 | SiC | 1 | μm | φ1 | μm | 2 | μm | 2 | 2 |
| 2-2 | (Y/X = 0.01) | 2 | μm | φ2 | μm | 3 | μm | 1 | 2 |
| 2-3 | | 3 | μm | φ3 | μm | 5 | μm | 1 | 1 |
| 2-4 | | 5 | μm | φ5 | μm | 8 | μm | 1 | 1 |
| 2-5 | | 10 | μm | φ10 | μm | 15 | μm | 1 | 1 |
| 2-6 | | 15 | μm | φ15 | μm | 23 | μm | 1 | 1 |
| 3-1 | SiC | 1 | μm | φ1 | μm | 2 | μm | 1 | 2 |
| 3-2 | (Y/X = 0.05) | 2 | μm | φ2 | μm | 3 | μm | 1 | 1 |
| 3-3 | | 3 | μm | φ3 | μm | 5 | μm | 1 | 1 |
| 3-4 | | 5 | μm | φ5 | μm | 8 | μm | 1 | 1 |
| 3-5 | | 10 | μm | φ10 | μm | 15 | μm | 1 | 1 |
| 3-6 | | 15 | μm | φ15 | μm | 23 | μm | 1 | 1 |
| 4-1 | SiC | 1 | μm | φ1 | μm | 2 | μm | 1 | 1 |
| 4-2 | (Y/X = 0.1) | 2 | μm | φ2 | μm | 3 | μm | 1 | 1 |
| 4-3 | | 3 | μm | φ3 | μm | 5 | μm | 1 | 1 |
| 4-4 | | 5 | μm | φ5 | μm | 8 | μm | 1 | 1 |
| 4-5 | | 10 | μm | φ10 | μm | 15 | μm | 1 | 1 |
| 4-6 | | 15 | μm | φ15 | μm | 23 | μm | 1 | 1 |
| 5-1 | SiCN | 1 | μm | φ1 | μm | 2 | μm | 2 | 2 |
| 5-2 | (N; 30 atom %) | 2 | μm | φ2 | μm | 3 | μm | 2 | 2 |
| 5-3 | (Y/X = 0.001) | 3 | μm | φ3 | μm | 5 | μm | 2 | 2 |
| 5-4 | | 5 | μm | φ5 | μm | 8 | μm | 1 | 1 |
| 5-5 | | 10 | μm | φ10 | μm | 15 | μm | 1 | 1 |
| 5-6 | | 15 | μm | φ15 | μm | 23 | μm | 1 | 1 |
| 6-1 | SiCN | 1 | μm | φ1 | μm | 2 | μm | 2 | 2 |
| 6-2 | (N; 30 atom %) | 2 | μm | φ2 | μm | 3 | μm | 1 | 2 |
| 6-3 | (Y/X = 0.01) | 3 | μm | φ3 | μm | 5 | μm | 1 | 1 |
| 6-4 | | 5 | μm | φ5 | μm | 8 | μm | 1 | 1 |
| 6-5 | | 10 | μm | φ10 | μm | 15 | μm | 1 | 1 |
| 6-6 | | 15 | μm | φ15 | μm | 23 | μm | 1 | 1 |
| 7-1 | SiCN | 1 | μm | φ1 | μm | 2 | μm | 1 | 2 |
| 7-2 | (N; 30 atom %) | 2 | μm | φ2 | μm | 3 | μm | 1 | 1 |
| 7-3 | (Y/X = 0.05) | 3 | μm | φ3 | μm | 5 | μm | 1 | 1 |
| 7-4 | | 5 | μm | φ5 | μm | 8 | μm | 1 | 1 |
| 7-5 | | 10 | μm | φ10 | μm | 15 | μm | 1 | 1 |
| 7-6 | | 15 | μm | φ15 | μm | 23 | μm | 1 | 1 |
| 8-1 | SiCN | 1 | μm | φ1 | μm | 2 | μm | 1 | 1 |
| 8-2 | (N; 30 atom %) | 2 | μm | φ2 | μm | 3 | μm | 1 | 1 |
| 8-3 | (Y/X = 0.1) | 3 | μm | φ3 | μm | 5 | μm | 1 | 1 |
| 8-4 | | 5 | μm | φ5 | μm | 8 | μm | 1 | 1 |
| 8-5 | | 10 | μm | φ10 | μm | 15 | μm | 1 | 1 |
| 8-6 | | 15 | μm | φ15 | μm | 23 | μm | 1 | 1 |

TABLE 2

| Compar- | Orifice | | | Discharge | | | | | Dis- |
|---|---|---|---|---|---|---|---|---|---|
| ative | Plate | OP | | Orifice | | Liquid | | | charge |
| Exam- | (OP) | Thick- | | Diam- | | Chamber | | OP | Orifice |
| ples | material | ness: A | | eter: B | | Height: C | | Shape | Shape |
| 1-1 | SiO | 1 | μm | φ1 | μm | 2 | μm | 3 | 3 |
| 1-2 | | 2 | μm | φ2 | μm | 3 | μm | 3 | 3 |
| 1-3 | | 3 | μm | φ3 | μm | 5 | μm | 3 | 3 |
| 1-4 | | 5 | μm | φ5 | μm | 8 | μm | 2 | 2 |
| 1-5 | | 10 | μm | φ10 | μm | 15 | μm | 2 | 2 |
| 1-6 | | 15 | μm | φ15 | μm | 23 | μm | 2 | 2 |
| 2-1 | SiN | 1 | μm | φ1 | μm | 2 | μm | 3 | 3 |
| 2-2 | | 2 | μm | φ2 | μm | 3 | μm | 3 | 3 |
| 2-3 | | 3 | μm | φ3 | μm | 5 | μm | 2 | 2 |
| 2-4 | | 5 | μm | φ5 | μm | 8 | μm | 2 | 2 |
| 2-5 | | 10 | μm | φ10 | μm | 15 | μm | 2 | 2 |
| 2-6 | | 15 | μm | φ15 | μm | 23 | μm | 1 | 1 |

Tables 1 and 2 show that the orifice plates in which when the content ratio of the silicon is defined as X (atom %) and the content ratio of the carbon is defined as Y (atom %), Y/X is 0.001 or more are hard to dissolve in liquid to be discharged and stably maintain the shape. It is found that Y/X is more suitably 0.01 or more and still more suitably 0.05 or more and 0.1 or more.

### Example 9

Example 9 is basically performed in the same manner as in Example 5-4 but, in Example 9, a film having a thickness of 0.5 micrometer containing silicon carbonitride given by a plasma CVD method was used as the protective film 11. The composition of the silicon carbonitride was the same as that of the orifice plate to be formed in the following process. A silicon oxide film having a film thickness of 2 micrometer to 23 micrometer was used as the molding member 24. First, silicon oxide was applied to a substrate by a CVD method, a resist containing a photosensitive resin was applied onto the applied silicon oxide film, and then the resist was exposed and developed to be used as a mask. The silicon oxide film was etched using the resist serving as the mask by RIE, thereby forming the molding member 24 serving as the mold of the flow path. The removal of the molding member 24 was performed using buffered hydrogen fluoride (BHF). Example 9 was performed in the same manner as in Example 5-4 except the conditions above.

With respect to the liquid discharge head manufactured in Example 9, the nozzle shape was able to be formed with higher accuracy since the molding member 24 was formed not by spin coating but by a plasma CVD method.

The silicon carbonitride contained in the orifice plate and the silicon carbonitride contained in the protective film have the same composition, and a liquid discharge head can be manufactured using a single film forming apparatus.

Since the protective film covering the energy generating element contains silicon carbonitride, the influence on the discharge orifice and the protective film was able to be reduced even when immersed in buffered hydrogen fluoride over a long period of time in order to increase the removability of the molding member 24.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-112718, filed May 16, 2012, which is hereby incorporated by reference herein in its entirety.

1. A liquid discharge head, comprising:
a substrate;
an energy generating element which generates energy for discharging liquid; and
an orifice plate in which a discharge orifice which discharges liquid is formed,
the orifice plate containing silicon and carbon and when the content ratio of silicon being defined as X (atom %) and the content ratio of carbon being defined as Y (atom %), Y/X being 0.001 or more.

2. The liquid discharge head according to claim 1, wherein the Y/X is 0.01 or more.

3. The liquid discharge head according to claim 1, wherein the Y/X is 0.05 or more.

4. The liquid discharge head according to claim 1, wherein the Y/X is 0.1 or more.

5. The liquid discharge head according to claim 1, wherein the orifice plate contains nitrogen.

6. The liquid discharge head according to claim 1, wherein the energy generating element is covered with a protective film and the protective film contains silicon carbonitride.

7. The liquid discharge head according to claim 6, wherein the orifice plate contains silicon carbonitride and the silicon carbonitride contained in the orifice plate and the silicon carbonitride contained in the protective film have the same composition.

8. The liquid discharge head according to claim 1, wherein the orifice plate is formed by a plasma CVD method.

9. A method for manufacturing a liquid discharge head having a substrate and an orifice plate in which a discharge orifice which discharges liquid is formed, the method comprising:
forming a molding member serving as a model of a flow path of liquid on a substrate;
forming a layer containing silicon and carbon in such a manner as to cover the molding member;
forming a discharge orifice in the layer containing silicon and carbon to form an orifice plate; and
removing the molding member and forming a flow path of liquid, the orifice plate containing silicon and carbon and when the content ratio of the silicon being defined as X (atom %) and the content ratio of the carbon being defined as Y (atom %), Y/X being 0.001 or more.
